(19) United States
(12) Patent Application Publication
(10) Pub. No.: US 2004/0178789 A1
(43) Pub. Date: Sep. 16, 2004

(54) Hands-free metal detector

(76) Inventors: Dominick A. Candelore III, Buena Vista, PA (US); Dominick A. Candelore SR., Buena Vista, PA (US)

Correspondence Address: BLYNN L. SHIDELER, THE BLK LAW GROUP, 3500 BROKKTREE ROAD, SUITE 200, WEXFORD, PA, 15090, US

(21) Appl. No.: 10/799,122

(22) Filed: Mar. 12, 2004

Related U.S. Application Data
(60) Provisional application No. 60/454,874, filed on Mar. 14, 2003.

(51) Int. Cl. G01N 27/72; G08B 13/24; G01R 33/00

(52) U.S. Cl. 324/226; 324/326; 324/329; 324/67; 340/551

(57) ABSTRACT

A metal detector that includes a substantially non-metallic housing that defines a hollow cavity and a human walking surface and a metal scanner element positioned in the hollow cavity defined by the non-metallic housing, wherein the walking surface receives a covered human foot. This invention allows travelers to leave their shoes on while transiting security checkpoints.

### RELATED APPLICATIONS

This application claims the benefit of pending provisional application serial No. 60/454,874 filed Mar. 14, 2003 entitled “Hands-Free Metal Detector” which is incorporated herein by reference in its entirety.

### BACKGROUND OF THE INVENTION

1. Field of the Invention

The present invention relates to metal detectors and, more particularly, to a hands free metal detector.

2. Brief Description of the Prior Art

Metal detectors, such as those commonly used at airport security checkpoints, are generally one of two types. The first type is a stationary metal detector that is designed to let a person walk through an opening defined by a rectangular-shaped frame. The second type is a hand-held wand type that is passed over the body of a traveler.

With increasing security requirements at airports all over the world, it is now common to require travelers to take off their shoes so that the shoes can be scanned for metallic items. This additional security precaution is recognized as an inconvenient necessity, but requiring air passengers to take off their shoes for scanning is both time consuming and, in some cases, embarrassing to certain passengers.

There is a need for a way to quickly and accurately check passenger shoes for the presence of metallic items, without requiring passengers to remove their shoes. The prior art metal detectors mentioned above are not wholly adequate for scanning shoes, because the rectangular-shaped metal detectors will sound an alarm if any metal passes through the rectangular detector. Therefore, passengers who activate an alarm while passing through the rectangular-shaped metal detector still have to be searched via a hand-held wand. This process significantly delays a passenger who may have inadvertently left a coin in a shirt pocket, because the passenger's entire body has to be scanned with the hand-held wand. Moreover, the search is overly intrusive, causes delays in the line of waiting passengers, and requires the need for additional security personnel armed with hand-held metal detection wands.

Scanning the shoes of travelers with a hand-held wand is also time consuming, physically exhausting, and more expensive in terms of employment costs.

### SUMMARY OF THE INVENTION

To help alleviate the deficiencies in the known prior art, the present invention provides a convenient, effective method and device for checking passer shoes for the presence of banned metallic articles.

One method, according to the present invention, generally includes steps of providing a stationary metal detector on a floor surface and positioning or passing a shoed human foot over the stationary metal detector.

A stationary metal detector, according to one embodiment of the present invention, generally includes a metal scanner element, means for fixing the stationary metal detector with respect to a floor surface, wherein the floor surface is preferably positioned before a secondary metal detector positioned after the stationary metal detector with respect to an established flow travelers, and means for indicating where a foot of a traveler should be positioned with respect to the stationary metal detector.

More specifically, the present invention contemplates a metal detector that includes a substantially non-metallic housing that defines a hollow cavity and a human walking surface, and a metal scanner element positioned in the hollow cavity defined by the non-metallic housing, wherein the walking surface receives a covered human foot.

### BRIEF DESCRIPTION OF THE DRAWINGS

FIG. 1 is a cross-sectional side view of a stationary metal detector according to one embodiment of the present invention;

FIG. 2 is a top view of the device shown in FIG. 1; and

FIGS. 3a and 3b are side views of several stationary metal detectors placed in a travel path indicated by arrow A1.

### DETAILED DESCRIPTION OF THE INVENTION

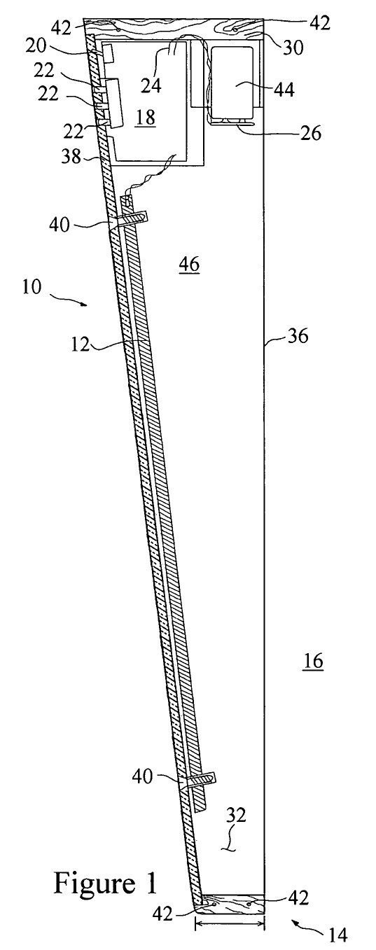

As shown in FIG. 1, a stationary metal detector 10, according to one embodiment of the present invention, generally includes a metal scanner element housed in a substantially non-metallic housing or frame 14, wherein the frame 14 is positioned in a stationary position with respect to a floor surface 16.

The metal scanner element 12 can be any suitable type of metal detector which will sense the presence of metal. Prototype testing has shown that Model 1165800 of the SUPERWAND brand of metal detectors, commercially available from GARRETT and incorporated by reference in its entirety, contains a suitable type of metal scanner element 12, along with a corresponding printed circuit board 18, an on-off switch 20, and light emitting diodes (LED's) 22. However, as discussed below, the Model 1165800 may be disassembled to separate the metal scanner element 12, the printed circuit board 18, the on-off switch 20, and the LEDs 22. Moreover, electrical power contacts 24 may be retrofitted with a nine-volt battery terminal 26 so that a nine-volt battery can be used as a power source.

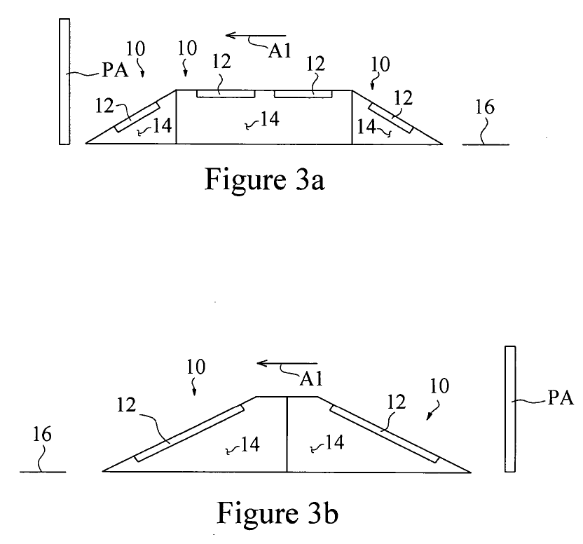

With continuing reference to FIG. 1, the frame 14 is preferably constructed from a non-metallic material such as wood (oak), a translucent or partially translucent plastic (plexiglas or clear plexiglas), a combination of wood and plastic, or any other suitable material. The wood forms the sides 28, 30, 32, 34 and an optional bottom (floor) portion 36 of the stationary metal detector 10, while the plastic forms a top or shoe contact portion 38. The top or shoe contact portion 38 of the frame 14 is preferably sloped with respect to the bottom portion 36 of the frame 14. This optional feature is designed to make it easier for a passenger to place a shoe on or near the shoe contact portion 38 of the frame 14 when the shoe contact portion 38 slopes toward an approaching passenger. In an alternative design, shown generally in FIGS. 3a and 3b, two or more frames 14 can be put together and possibly inclined in two opposed directions, so that a person can continuously walk over the two frames 14 without stopping. The frame 14 can also define a substantially planar walking surface that is parallel to the floor 16.

The frame 14 may held together with fasteners, such as No. 8 or No. 10 TEFLON screws 40, and two inch ten penny wood finishing nails 42. The nails 42, which are made from metal, can be used to fasten each side 28, 30, 32, 34 of the frame 14 to an adjacent side or the sides to the bottom 36. However, non-metallic fasteners should be used within ten inches in any direction as measured from the metal scanner element 12.

The metal scanner element 12, printed circuit board 18 and power source 44 are preferably housed within a hollow cavity 46 defined by the sides, bottom, and top portion of the frame 14. The on-off switch 20 and the LEDs 22 may be entirely housed within the hollow cavity 46, or may protrude through the frame 14. FIG. 1 shows the LEDs 22 and the on-off switch 20 partially protruding through the top portion 38 of the frame 14. If all of the operational components and electronics are housed within the hollow cavity 46 defined by the frame 14, any portion of the frame 14 may be hinged at one end so that the hollow cavity 46 can be accessed for component activation, deactivation, or replacement. A lock (not shown) may be provided on the hinged frame part to help reduce unauthorized access to the metal scanner element 12, printed circuit board 18, power source 44, on-off switch 20, or LEDs 22.

More specifically, as shown in FIG. 1, the metal scanner element 12 is preferably positioned immediately adjacent to the shoe contact portion 38 of the frame 14 and may be mounted by non-metallic mounts, such as plastic mounts fastened with non metallic fasteners, such as No. 8 or No. 10 TEFLON screws. The LEDs 22, which are electrically connected to the printed circuit board 18 and preferably indicate power, alarm, and power warning, should be visible to an observer at all times but may be mounted or otherwise positioned in any suitable orientation with respect to any portion of the frame 14. Similarly, the printed circuit board 18 is electrically connected to the metal scanner element 12, and the power supply 44 is electrically connected to the printed circuit board 18 and the on-off switch 20, which may also be mounted or otherwise positioned in any suitable orientation with respect to any portion of the frame 14.

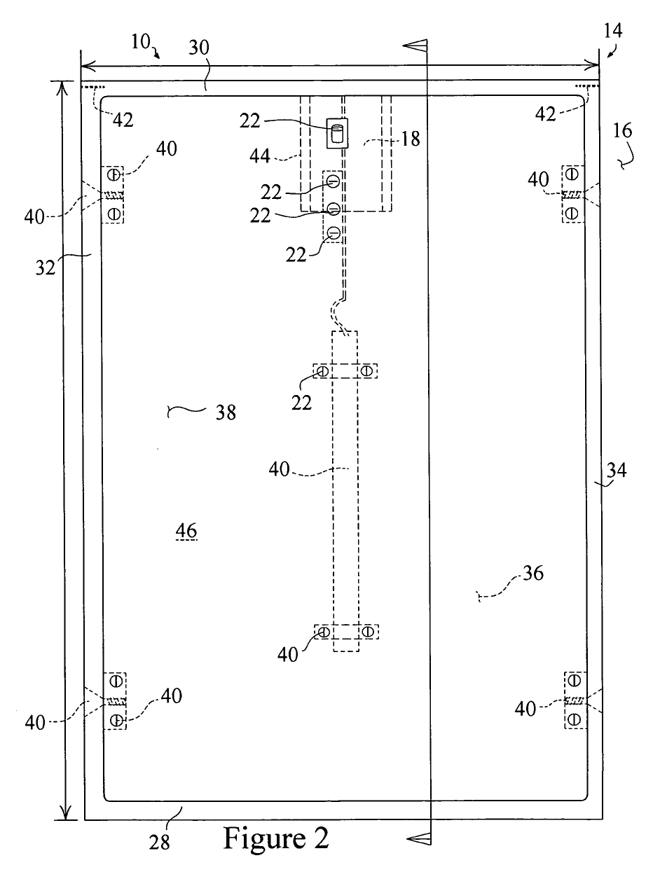

As shown in FIG. 2, indicia 48 can be added to the shoe contact portion 38 of the frame 14 to help a traveler position his or her shoed foot over the metal scanner element 12. The indicia 48 can take any suitable shape, such as an outline of a footprint, a company logo, a face of a known terrorist, or any other symbol or shape. Traction treads may also be used for safety.

In a preferred method of operation, a stationary metal detector 10 according to the present invention is positioned on a floor surface 16. It is envisioned, as shown in FIGS. 3a and 3b, that a stationary metal detector 10, such as the one shown in FIGS. 1 and 2, is positioned in a flow of commuter traffic A1 such that a traveler encounters the stationary metal detector or detectors 10 prior to passing through the prior art rectangular, open-frame type of metal detector PA. When the traveler encounters the stationary metal detector 10, he or she places his/her shoed foot over, on, or immediately adjacent to the metal scanner element 12 contained within the stationary metal detector 10. As noted above, the shoe contact surface can initially slope toward the traveler for comfort, or slope in two directions if two stationary metal detectors are placed in series. If no alarm sounds, the traveler removes his/her foot and places his/her remaining foot over, on, or immediately adjacent to the metal scanner element 12. Alternatively, if two or more stationary metal detectors 10 are used along a human walking travel path A1, the traveler can continue walking. If no alarm sounds, the traveler proceeds to the prior metal detector, and subsequently passes through the secondary metal detector. If the secondary metal detector senses a metallic object, the shoes can be excluded as the cause.

In another method of operation, shown generally in FIG. 3b, the stationary metal detector 10 is positioned after the prior art metal detector PA and is used to quickly locate or exclude the cause of a metal detector alarm. As noted above, this process can be accomplished by placing each shoed foot over, on, or otherwise immediately adjacent to the metal scanner element contained in the frame or frames.

In summation, the present invention provides an efficient, time saving, and cost-effective method of checking passenger shoes for prohibited metallic objects, such as knives, razors, etc. Traffic lines are not disrupted by passengers re-shoeing their stocking feet, the embarrassment of a sock hole is eliminated, and shoes can quickly be eliminated as the cause of a secondary, prior art metal detection alarm.

The invention has been described with reference to the preferred embodiment. Obvious modifications and alterations will occur to others upon reading and understanding the preceding detailed description. For example, Strengthening ribs or struts could be added to the detector 10 without changing the scope of the invention. It is intended that the invention be construed as including all such modifications and alterations insofar as they come within the scope of the appended claims or the equivalents thereof

I claim:

1. A metal detector comprising:
a substantially non-metallic housing that defines a hollow cavity and a human walking surface; and
a metal scanner element positioned in the hollow cavity defined by the non-metallic housing,
wherein the walking surface receives a covered human foot.

2. The metal detector as claimed in claim 1, wherein the substantially non-metallic housing is plastic.

3. The metal detector as claimed in claim 1, wherein the substantially non-metallic housing is partially translucent.

4. The metal detector as claimed in claim 1, wherein the human walking surface defined by the substantially non-metallic housing is inclined with respect to a planar human walking surface.

5. The metal detector as claimed in claim 1, further comprising indicia positioned adjacent to the human walking surface of the substantially non-metallic housing.

6. The metal detector as claimed in claim 1, wherein the metal scanner element is a wand-type metal scanner.

7. The metal detector as claimed in claim 1, wherein a device selected from the group comprising an on/off switch, a battery source, and an LED is also positioned in the hollow cavity.

8. The metal detector as claimed in claim 1, further comprising a second metal detector positioned adjacent to the metal detector, the second metal detector comprising:
a second substantially non-metallic housing that defines a second hollow cavity and a second human walking surface; and
a second metal scanner element positioned in the second hollow cavity defined by the second non-metallic housing,
wherein the human walking surface and the second human walking surface each receive a covered human foot.

9. The metal detector as claimed in claim 8, wherein the human walking surface defined by the substantially non-metallic housing is angled with respect to a planar human walking surface.

10. The metal detector as claimed in claim 8, wherein the second human walking surface defined by the substantially non-metallic housing is angled with respect to a planar human walking surface.

11. A method to check human shoes, socks, and feet for metal objects comprising the steps of:
a) providing a stationary metal detector on a floor surface; and
b) positioning a shoed human foot on the stationary metal detector.

12. The method as claimed in claim 11, further comprising the step of passing a shoed human foot over the stationary metal detector in place of step a).
